(19) United States
(12) Patent Application Publication
(10) Pub. No.: US 2012/0115310 A1
(43) Pub. Date: May 10, 2012

(54) METHOD OF SIGE EPITAXY WITH HIGH GERMANIUM CONCENTRATION

(76) Inventors: Yan Miu, Shanghai (CN); Wei Ji, Shanghai (CN)

(21) Appl. No.: 13/288,869

(22) Filed: Nov. 3, 2011

(30) Foreign Application Priority Data
Nov. 5, 2010 (CN) 201010533250.3

(51) Int. Cl. H01L 21/20

(52) U.S. Cl. 438/478; 257/E21.09

(57) ABSTRACT

The present invention discloses a method of SiGe epitaxy with high germanium concentration, a germanium concentration can be increased by reducing the percentage of silane and germane during introduction silane and germane. With the same flow of germanium source, the germanium concentration is significantly increased as the germane flow is reduced, therefore a defect-free SiGe epitaxial film with a germanium atomic percentage of 25˜35% can be obtained. The present invention can balance epitaxial growth rate and germanium doping concentration by using existing equipments to obtain a high germanium concentration, and the epitaxial growth rate is only reduced a little, which can keep the SiGe epitaxial layer having no defect to meet the requirements of devices and can maintain sufficient throughput.

### CROSS-REFERENCES TO RELATED APPLICATIONS

This application claims the priority of Chinese patent application number 201010533250.3, filed on Nov. 5, 2010, the entire contents of which are incorporated herein by reference.

### TECHNICAL FIELD

The present invention relates to a semiconductor manufacturing method, especially to a method of forming SiGe epitaxial layer with high germanium concentration.

### BACKGROUND OF THE INVENTION

Silicon-germanium (SiGe) has become another important semiconductor material other than Si and GaAs and has a better performance than pure Si material. The manufacturing process of SiGe is compatible with a silicon process. Electrical performances of SiGe heterojunction bipolar transistor (HBT) can nearly reach the same level as those of the same kind of devices made of compound semiconductor material like GaAs. Therefore, SiGe HBT has a broad application prospect in the field of RF (radio frequency) especially ultra high frequency. Moreover, SiGe HBT can be integrated with CMOS process to exploit the high-integration and low-cost advantages of the CMOS process, further to realize high-frequency and low-noise performances of SiGe/Si HBT.

As the forbidden band width of germanium is relatively narrow, e.g. the forbidden band width of germanium is about 0.67 eV (that of silicon is 1.12 eV), by combining germanium with silicon, an accelerating electric field can be formed in the base region to achieve rapid transport of carriers and high frequency characteristics of devices. From the expression of HBT's current gain β=(N_{E}W_{E}D_{B}/N_{B}W_{B}D_{E}) *exp(ΔEg/kt), it can be found that, the value of β can be improved by increasing germanium concentration (related to Eg), so that the value of β can be guaranteed and meanwhile the doping concentration of the base region can be improved, therefore the base transit time can be reduced and the high-frequency characteristics can be improved. In theory, the germanium concentration should be as high as possible, but according to the literatures available as so far, the germanium concentration is generally less than 20% (atomic percentage), moreover, there is no disclosed specific growing method for SiGe epitaxial layer with higher germanium concentration for the following restrictions: first, since SiGe epitaxy is a process based on a Si epitaxial process and increases the concentration of germanium, there could be a large mismatch, which may easily cause defects; second, although the germanium concentration can be improved by reducing the epitaxial growth temperature, the epitaxial growth rate is greatly reduced, for example, according to the results of experiments, if the growth temperature decreases 30° C., the growth rate is reduced to one-third of the original, therefore the throughput will be reduced, meanwhile the germanium concentration improved by the way of reducing the epitaxial growth temperature is limited, e.g. when the epitaxial growth temperature decreases 30° C., the germanium concentration is only improved by 2%; third, although the germanium concentration can also be improved by increasing germane flow, the improvement of the germanium concentration is limited because the epitaxial growth rate will increase as the germane flow increases, for example, a maximum germane flow only contributes to 2% of the increase of the germanium concentration. For the third method above, to obtain a high germanium concentration, a germane flowmeter is needed to be additionally designed. In present practice of 10%-20% germanium concentration, two germane flowmeters should be arranged to obtain a germanium gradient (i.e., the germanium concentration gradually declines from high to low), therefore at least three germane flowmeters are needed to obtain an epitaxial layer with high germanium concentration, which will increase equipment cost and process complexity.

### SUMMARY OF THE INVENTION

An objective of the present invention is to provide a method of forming a SiGe epitaxial layer with high germanium concentration, which can not only obtain a high germanium concentration, e.g. the atomic percentage of germanium is 25-35%, but also keep the SiGe epitaxial layer having no defect to meet the requirements of devices and maintain sufficient throughput.

To achieve the above objective, a method of forming a SiGe epitaxial layer with high germanium concentration according to the present invention is provided. During introduction of silane and germane, reducing the ratio of the silane to the germane can increase the content of germanium in the SiGe epitaxial layer. With the same flow of germanium source gas, the germanium concentration is significantly increased as the flow of silicon source gas is reduced, and a defect-free SiGe epitaxial film with a germanium atomic percentage of 25˜35% can be obtained.

A high germanium concentration region in the SiGe epitaxial film is grown by maintaining a partial pressure of silane at a low level, i.e., the germanium concentration is improved by reducing the silane flow.

During the growth of a high germanium concentration region, the silane flow is 20˜50 sccm, the germane flow is 300˜500 sccm and the ratio of the silane flow to the germane flow is 1/20˜1/5.

The germanium has a trapezoidal, rectangular or triangular distribution in the SiGe epitaxial film.

To form a trapezoidal distribution of the high germanium concentration in the SiGe epitaxial film, a first low germanium concentration region, a high germanium concentration region and a second low germanium concentration region are grown in order by using a method as follows: first, growing the first low germanium concentration region by maintaining a partial pressure of silane at a high level (the first silane partial pressure), wherein, the ratio of the silane flow to the germane flow is 1/3.5˜1/0 (1/0 indicates that the germane flow is minimized to 0 sccm), the germane flow is 0˜100 sccm and the silane flow is 50˜200 sccm; then switching the partial pressure of the silane to a low level (the second silane partial pressure) to grow the high germanium concentration region, wherein, the ratio of the silane flow to the germane flow is 1/20˜1/5, the silane flow is 20˜50 sccm and the germane flow is 300˜500 sccm; finally switching the partial pressure of silane again to a high level (the third silane partial pressure) to grow the second low germanium concentration region, wherein the ratio of the silane flow to the germane flow is 1/3.5˜1/0, the germane flow is 0˜100 sccm and the silane flow is 50˜200 sccm.

To form a trapezoidal distribution of the high germanium concentration in the SiGe epitaxial layer, a Si buffer layer, a SiGe layer, and a Si capping layer is grown in order by using a method as follows: first, growing the Si buffer layer by maintaining a partial pressure of silane at a high level, wherein, the germane flow is 0 sccm and the silane flow of 50˜200 sccm, therefore the Si buffer layer has no germanium, i.e. the germanium concentration is zero; then switching the partial pressure of silane to a low level to grow the SiGe layer, wherein, the ratio of the silane flow to the germane flow is 1/20˜1/5, the silane flow is 20˜50 sccm and the germane flow is 300˜500 sccm; finally switching the partial pressure of silane again to a high level to grow the Si capping layer, wherein, the germane flow is 0 sccm and the silane flow is 50˜200 sccm, therefore the germanium concentration of the Si capping layer is zero.

The single crystal region of the SiGe epitaxial layer is a defect-free single crystal.

The SiGe epitaxial layer is grown by a reduced pressure chemical vapor deposition process, wherein the growth pressure is 60˜700 Torr, silane gas serves as silicon source gas, germane gas serves as germanium source gas, hydrogen serves as a carrier gas and the growth temperature is 600˜680° C.

The concentration of boron in the SiGe epitaxial layer is 1E18˜5E20/cm³ and the concentration of carbon in the SiGe epitaxial layer is 1E19˜5E20/cm³.

Compared to the prior arts, the advantages of the present invention are as follows: a method of forming a SiGe epitaxial layer with high germanium concentration according to the present invention can obtain a SiGe epitaxial layer with high germanium concentration under a lower temperature such as 600˜680° C. by utilizing existing equipments without additional germanium source and flowmeters, and the atomic percentage of the germanium concentration can reach about 25˜35%. Through this method, a stable pressure control and a defect-free SiGe epitaxial layer can be obtained, meeting the requirements of devices. As shown in FIG. 4 and FIG. 5, a SiGe epitaxial single crystal region is in the form of a perfect single crystal without defect.

### BRIEF DESCRIPTION OF THE DRAWINGS

FIG. 1 is a schematic diagram showing the depth distribution of a SiGe epitaxial layer, wherein 1 is a Si capping layer; 2 is a SiGe layer; 3 is a Si buffer layer; 4 is a first low germanium concentration region; 5 is a high germanium concentration region; 6 is a second low germanium concentration region;

FIG. 2 is a schematic diagram showing the germanium doping concentration with various ratios of a silicon source to a germanium source according to the present invention;

FIG. 3 is a schematic diagram showing the doping status of germanium in SiGe epitaxial layer according to the present invention;

FIG. 4 is a SEM top view of the SiGe epitaxial layer with high germanium concentration according to the present invention;

FIG. 5 is a SEM cross-sectional view of a single crystal region of the SiGe epitaxial layer with high germanium concentration according to the present invention.

### DETAILED DESCRIPTION OF THE INVENTION

The present invention will be further described and specified in combination with drawings and embodiments.

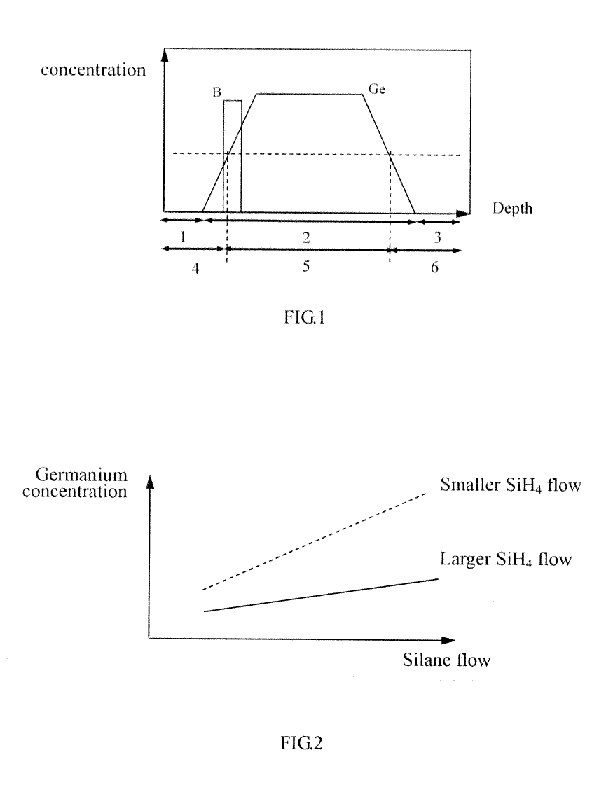

The present invention discloses a method of forming a SiGe epitaxial layer with high germanium concentration, by which the germanium (Ge) concentration in SiGe epitaxial layer can be increased by reducing the ratio of silane to germane during the process of SiGe epitaxial growth. FIG. 2 shows the germanium doping concentration with various ratios of a silicon source gas to a germanium source gas according to the present invention. As shown in FIG. 2, with the same flow of germanium source, the germanium concentration is significantly increased as the flow of the silicon source (i.e. silane) is decreased (the smaller SiH₄ flow in FIG. 2), while the germanium concentration will increase as the flow of germanium source (i.e. germane) increases, however, the increase of the germane flow has a less impact on the improvement of the germanium concentration than the decrease of the silane flow.

When the partial pressure ratio of silane to germane is reduced (reducing the silane flow, while keeping the germane flow constant), the deposition rate of the epitaxial layer will decrease. For instance, the deposition rate of the epitaxial layer is reduced by about 10% when the silane flow is reduced from 60 sccm to 40 sccm. The reduction of the deposition rate will improve Ge doping concentration, which will increase the deposition rate in return, therefore, the deposition rate of the epitaxial layer is only reduced by approximately 10%, less than the percentage of the reduction of the silane flow. In this way, the present invention can obtain a defect-free SiGe epitaxial layer with a germanium atomic percentage of 25˜35%.

The SiGe epitaxial layer of the present invention is grown by a reduced pressure chemical vapor deposition (RPCVD) process, wherein the growth pressure is 60˜700 Torr; silane (SiH₄) serves as silicon source gas; germane (GeH₄) serves as germanium source gas; hydrogen (H₂) serves as carrier gas; and the growth temperature is 600˜680° C.

The advantages of the present invention are balancing the epitaxial growth rate and germanium doping concentration and obtaining a high germanium concentration by utilizing the current equipments, meanwhile succeeding in a minor loss of epitaxial growth rate.

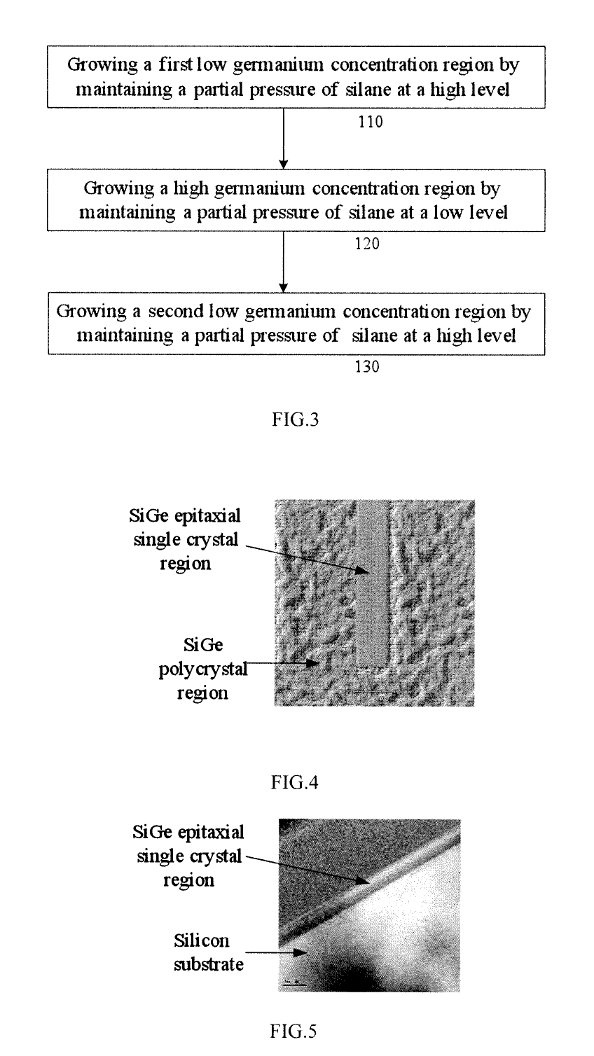

FIG. 1 is a schematic diagram showing the depth distribution of a SiGe epitaxial layer, wherein the germanium concentration is trapezoidal distributed and the maximum germanium concentration is the atomic percentage of 25˜35%. In FIGS. 1, 4 and 6 are low germanium concentration regions and 5 is a high germanium concentration region. FIG. 3 shows the doping status of germanium in the SiGe epitaxial layer according to the present invention. The germanium doping method of the SiGe epitaxial layer comprises: first growing a low germanium concentration region by maintaining a partial pressure of silane at a high level; then switching the partial pressure of silane to a low level to grow a high germanium concentration region; finally switching the partial pressure of silane again to a high level to grow another low germanium concentration region, wherein the partial pressure of silane at a high level indicates a larger value of silane flow/germane flow (i.e., the ratio of a silane flow to a germane flow), while the partial pressure of silane at a low level indicates a smaller value of silane flow/germane flow. The growth of high germanium concentration region in the SiGe epitaxial layer of the present invention is achieved by maintaining the partial pressure of silane to a low level, i.e., the germanium concentration is improved by reducing the silane flow, which is different from the existing method of improving the germanium concentration by increasing the germane flow. During the growth of the high germanium concentration region, the silane flow is 20˜50 sccm, the germane flow is 300˜500 sccm, wherein the target concentration of the silane is 100%, the target concentration of the germane is 1.5%, when the actual silane concentration and/or the actual germane concentration are different from the respective target concentrations, the flow of the silane and/or the flow of the germane need to be adjusted: suppose when the concentration of the silane is 100% and the concentration of the germane is 1.5%, the silane flow is A and the germane flow is B; if the actual silane concentration and germane concentration are respectively a % and b %, the corresponding silane flow A′ and the corresponding germane flow B′ shall be redetermined by using the formulas: A*100%=A′*a %, B*1.5%=B′*b %, in this way adjusting the ratio of the silane flow to the germane flow; the ratio of the silane flow to the germane flow can be selected from 1/20˜1/5. Germanium has a trapezoidal, rectangular or triangular distribution in the SiGe epitaxial film.

For the depth distribution of a SiGe epitaxial layer as shown in FIG. 1, regions are grown in order from right to left, i.e., the low germanium concentration region 6->the high germanium concentration region 5->the low germanium concentration region 4.

### Embodiment 1

for forming the trapezoidal distribution of germanium concentration as shown in FIG. 1, first grow the low germanium concentration region 6 (Step 110) by maintaining a partial pressure of silane at a high level (the ratio of a silane flow to a germane flow of 1/3.5˜1/0, 1/0 indicates that the germane flow is minimized to 0 sccm, the germane flow is 0˜100 sccm and the silane flow is 50˜200 sccm); then, switch the partial pressure of silane to a low level (the ratio of the silane flow to the germane flow is 1/20˜1/5, the silane flow is 20˜50 sccm and the germane flow is 300˜500 sccm) to grow the high germanium concentration region 5 (Step 120); switch the partial pressure of silane again to a high level (the ratio of the silane flow to the germane flow is 1/3.5˜1/0, 1/0 indicates that the germane flow is minimized to 0 sccm, the germane flow is 0˜100 sccm and the silane flow is 50˜200 sccm) to grow another low germanium concentration region 4 (Step 130); finally form a depth distribution of impurities as shown in FIG. 1.

### Embodiment 2

for forming the trapezoidal distribution of germanium concentration shown in FIG. 1, first grow a Si buffer layer 3 (not containing germanium, i.e. having a germanium concentration of zero) (Step 110) by maintaining a partial pressure of the silane at a high level (the first silane partial pressure, i.e. the ratio of the silane flow to the germane flow is 1/0, e.g., the germane flow is 0 sccm and the silane flow is 50˜200 sccm); then switch the partial pressure of silane to a low level (the ratio of the silane flow to the germane flow is 1/20˜1/5, the silane flow is 20˜50 sccm and the germane flow is 300˜500 sccm) to grow a SiGe layer 2 (Step 120); switch the partial pressure of silane again to a high level (the ratio of the silane flow to the germane flow is 1/0, e.g., the germane flow is 0 sccm and the silane flow is 50˜200 sccm) to grow a Si capping layer 1 (not containing germanium, i.e. having a germanium concentration of zero) (Step 130); finally form a depth distribution of impurities as shown in FIG. 1.

The above methods can also be applied to improve a concentration of boron or carbon in the epitaxial layer.

And the boron concentration can be 1E18˜5E20/cm³ and the carbon concentration can be 1E19˜5E20/cm³.

What is claimed is:

1. A method of forming a SiGe epitaxial layer with high germanium concentration, comprising: reducing a ratio of a silicon source gas to a germanium source gas introduced during a SiGe epitaxial growth to increase a germanium concentration in the SiGe epitaxial layer.

2. The method of forming a SiGe epitaxial layer with high germanium concentration according to claim 1, wherein the ratio of the silicon source gas to the germanium source gas introduced is reduced by reducing a flow of the silicon source gas and keeping a flow of the germanium source gas constant.

3. The method of forming a SiGe epitaxial layer with high germanium concentration according to claim 2, wherein the silicon source gas is silane, the germanium source gas is germane.

4. The method of forming a SiGe epitaxial layer with high germanium concentration according to claim 3, wherein a flow of the silane is 20˜50 sccm, and a flow of the germane is 300˜500 sccm.

5. The method of forming a SiGe epitaxial layer with high germanium concentration according to claim 4, wherein a target concentration of the silane is 100% and a target concentration of the germane is 1.5%; when an actual concentration of silane and/or an actual concentration of germane are different from the target concentrations, the flow of the silane and/or the flow of the germane need to be adjusted.

6. The method of forming a SiGe epitaxial layer with high germanium concentration according to claim 4, wherein a ratio of the flow of the silane to the flow of the germane is 1/20˜1/5.

7. The method of forming a SiGe epitaxial layer with high germanium concentration according to claim 3, wherein the SiGe epitaxial layer is grown by a reduced pressure chemical vapor deposition process, wherein a growth pressure is 60˜700 Torr, a carrier gas is hydrogen, a growth temperature is 600-680° C.

8. The method of forming a SiGe epitaxial layer with high germanium concentration according to claim 3, wherein germanium in the SiGe epitaxial layer has a trapezoidal, rectangular or triangular distribution.

9. The method of forming a SiGe epitaxial layer with high germanium concentration according to claim 8, wherein the germanium in the SiGe epitaxial layer has a trapezoidal distribution, the SiGe epitaxial layer comprising a first low germanium concentration region, a high germanium concentration region and a second low germanium concentration region in order.

10. The method of forming a SiGe epitaxial layer with high germanium concentration according to claim 9, wherein a method of growing the SiGe epitaxial layer comprises:
forming the first low germanium concentration region by a first silane partial pressure;
forming the high germanium concentration region by a second silane partial pressure;
forming the second low germanium concentration region by a third silane partial pressure, wherein
both the first silane partial pressure and the third silane partial pressure are larger than the second silane partial pressure.

11. The method of forming a SiGe epitaxial layer with high germanium concentration according to claim 10, wherein in the first silane partial pressure, a ratio of the flow of the silane to the flow of the germane is 1/3.5˜1/0, the flow of the germane is 0˜100 sccm and the flow of the silane is 50˜200 sccm; in the second silane partial pressure, a ratio of the flow of the silane to the flow of the germane is 1/20˜1/5, the flow of the germane is 20˜50 sccm and the flow of the silane is 300˜500 sccm: in the third silane partial pressure, a ratio of the flow of the silane to the flow of the germane is 1/3.5˜1/0, the flow of the germane is 0˜100 sccm and the flow of the silane is 50˜200 sccm.

12. The method of forming a SiGe epitaxial layer with high germanium concentration according to claim 11, wherein a target concentration of the silane is 100% and a target concentration of the germane is 1.5%; when an actual concentration of silane and/or an actual concentration of germane are different from the target concentrations, the flow of the silane and/or the flow of the germane need to be adjusted.

13. The method of forming a SiGe epitaxial layer with high germanium concentration according to claim 12, wherein the first low germanium concentration region is a Si buffer layer, the high germanium concentration region is a SiGe layer and the second low germanium concentration region is a Si capping layer.

14. The method of forming a SiGe epitaxial layer with high germanium concentration according to claim 13, wherein the flow of the germane is 0 sccm and the flow of the silane is 50˜200 sccm during growing the Si buffer layer; the ratio of the flow of the silane to the flow of the germane is 1/20˜1/5, the flow of the silane is 20˜50 sccm and the flow of the germane is 300˜500 sccm during growing the SiGe layer; the flow of the germane is 0 sccm and the flow of the silane is 50˜200 sccm during growing the Si capping layer.

15. The method of forming a SiGe epitaxial layer with high germanium concentration according to claim 14, wherein a target concentration of the silane is 100% and a target concentration of the germane is 1.5%; when an actual concentration of silane and/or an actual concentration of germane are different from the target concentrations, the flow of the silane and/or the flow of the germane need to be adjusted.

16. The method of forming a SiGe epitaxial layer with high germanium concentration according to claim 1, further comprising: reducing a ratio of a silicon source gas to a carbon source gas introduced during SiGe epitaxial growth to increase a carbon concentration in the SiGe epitaxial layer

17. The method of terming a SiGe epitaxial layer with high germanium concentration according to claim 16, wherein the ratio of the silicon source gas to the carbon source gas is reduced by reducing a flow of the silicon source gas and keeping a flow of the carbon source gas constant.

18. The method of forming a SiGe epitaxial layer with high germanium concentration according to claim 1, further comprising: reducing a ratio of a silicon source gas to a boron source gas introduced during SiGe epitaxial growth to increace a boron concentration in the SiGe epitaxial layer.

19. The method of forming a SiGe epitaxial layer with high germanium concentration according to claim 18, wherein the ratio of the silicon source gas to the boron source gas is reduced by reducing a flow of the silicon source gas and keeping a flow of the boron source gas constant.
